(19) United States
(12) Patent Application Publication
(10) Pub. No.: US 2016/0225459 A1
(43) Pub. Date: Aug. 4, 2016

(54) APPARATUSES OPERABLE IN MULTIPLE POWER MODES AND METHODS OF OPERATING THE SAME

(71) Applicant: Micron Technology, Inc., Boise, ID (US)

(72) Inventors: Adam N. Boysan, Sacramento, CA (US); Jeffrey Mcvay, El Dorado Hills, CA (US)

(21) Appl. No.: 14/609,922

(22) Filed: Jan. 30, 2015

(51) Int. Cl. G11C 16/30; G11C 11/56

(52) U.S. Cl. CPC G11C 16/30; G11C 11/5621

(57) ABSTRACT

The present disclosure is related to apparatuses operable in multiple power modes and methods of operating the same. An example embodiment includes an apparatus comprising a memory comprising an array of memory cells operable to store single-level cell (SLC) data and multi-level cell (MLC) data. The apparatus can include a controller coupled to the memory and configured to: responsive to the apparatus being in a first power mode, fold SLC data into MLC data; and prevent SLC data from being folded into MLC data responsive to the apparatus being in a second power mode.

### TECHNICAL FIELD

The present disclosure relates generally to semiconductor memory and methods, and more particularly, to apparatuses operable in multiple power modes and methods of operating the same.

### BACKGROUND

Memory devices are typically provided as internal, semiconductor, integrated circuits in computers or other electronic devices. There are many different types of memory including volatile and non-volatile memory. Volatile memory can require power to maintain its data (e.g., host data, error data, etc.) and includes random-access memory (RAM), dynamic random access memory (DRAM), and synchronous dynamic random access memory (SDRAM), among others. Non-volatile memory can provide persistent data by retaining stored data when not powered and can include NAND flash memory, NOR flash memory, read only memory (ROM), Electrically Erasable Programmable ROM (EEPROM), Erasable Programmable ROM (EPROM), and resistance variable memory such as phase change random access memory (PCRAM), resistive random access memory (RRAM), and magnetoresistive random access memory (MRAM), among others.

Memory devices can be combined together to form a storage volume of a memory system such as a solid state drive (SSD). A solid state drive can include non-volatile memory (e.g., NAND flash memory and NOR flash memory), and/or can include volatile memory (e.g., DRAM and SRAM), among various other types of non-volatile and volatile memory. Various electronic devices, such as portable electronic devices, rely on a direct current (DC) power source (e.g., a battery) when not connected to an alternating current (AC) power source. Therefore, extending the battery life of such devices can be beneficial.

### BRIEF DESCRIPTION OF THE DRAWINGS

FIG. 1 illustrates a schematic diagram of a portion of a memory array operable in accordance with a number of embodiments of the present disclosure.

FIG. 2A is a diagram of a number of threshold voltage distributions corresponding to single-level cell (SLC) data.

FIG. 2B is a diagram of a number of threshold voltage distributions corresponding to multi-level cell (MLC) data.

FIG. 3 is a block diagram of an apparatus in the form of a computing system including at least one memory system in accordance with a number of embodiments of the present disclosure.

FIG. 4 is a flow chart illustrating a method of operating an apparatus in accordance with a number of embodiments of the present disclosure.

### DETAILED DESCRIPTION

The present disclosure is related to apparatuses operable in multiple power modes and methods of operating the same. An example embodiment includes an apparatus comprising a memory comprising an array of memory cells operable to store single-level cell (SLC) data and multi-level cell (MLC) data. The apparatus can include a controller coupled to the memory and configured to: responsive to the apparatus being in a first power mode, fold SLC data into MLC data; and prevent SLC data from being folded into MLC data responsive to the apparatus being in a second power mode.

As used herein, a SLC is a memory cell configured to store a single bit of data (e.g., a cell programmable to one of two states). A MLC is a memory cell configured to store more than a single bit of data (e.g., a cell programmable to one of more than two states). As an example, some MLCs are programmable to one of four states such that they store 2 bits of data, and some MLCs are programmable to one of eight states such that they store 3 bits of data. It is also possible for MLCs to store a non-integer number of bits. For instance, a cell programmable to one of three states can store 1.5 bits of data.

There can be various reasons for storing data in memory as SLC data or MLC data. For instance, data stored as SLC data may be more reliable (e.g., less prone to errors) than data stored as MLC data due to the reduced read margins associated with MLCs, for example. However, storing data as MLC data can provide increased storage capacity of a memory. Therefore, in various instances, it can beneficial to fold SLC data into MLC data, which can refer to rewriting SLC data as MLC data (e.g., in the same cells or different cells). One potential drawback to folding SLC data into MLC data is that programming MLC data often consumes more power per bit of data as compared to programming SLC data. Although folding SLC data into MLC data can be performed as a background process (e.g., such that a user may be unaware of the folding), the folding process consumes power, which reduces the battery life of an apparatus operating in a direct current (DC) mode (e.g., an apparatus that is not plugged into an AC power source such that it is operating on battery power), and also reduces resources available for performing user requested processes (e.g., I/O requests). Garbage collection, which is another process that can be performed in the background, also consumes power and so reduces the battery life of the apparatus and the resources available for performing I/O requests, for instance. As used herein, garbage collection can refer to a memory management process in which blocks of memory cells having more than a threshold amount of invalid and/or stale pages are reclaimed (e.g., by reading and rewriting the valid pages to an erased block). Garbage collection may occur as part of a wear leveling process and can affect the write amplification associated with the memory.

In various previous memory apparatuses, data folding and/or garbage collection occurred without regard to the power mode of the apparatus. For example, such operations were performed whether the apparatus were in a DC power mode (e.g., operating via battery power) or an AC power mode (e.g., plugged into an AC power source such as an AC power outlet). As such, data folding and garbage collection processes resulted in reduced performance and/or reduced useful lifetime (e.g., battery life) of an apparatus. Reduced battery life can be detrimental for various apparatuses such as laptops, cell phones, digital cameras, and/or various other mobile devices.

A number of embodiments of the present disclosure can provide benefits such as increasing the battery life and/or performance of a device. In a number of embodiments, the performance of operations such as data folding and/or garbage collection can be based on a variety of factors. For example, in a number of embodiments, the determination of whether data folding and/or garbage collection occurs is based on the power mode of an apparatus. For instance, data folding and/or garbage collection may be reserved for instances in which the apparatus is operating in an AC power mode (e.g., plugged in), such that data folding and/or garbage collection is delayed while the apparatus is in a DC power mode (e.g., operating on battery power). As described further herein, the timing of when operations such as data folding and/or garbage collection are performed can be based on a number of other factors including, but not limited to, the capacity of a DC power source (e.g., remaining battery life), the available storage capacity of the system, the amount and/or status of cold data, the amount of unanswered I/O requests, and/or the amount of garbage collection opportunities available, among various other factors.

In the following detailed description of the present disclosure, reference is made to the accompanying drawings that form a part hereof, and in which is shown by way of illustration how a number of embodiments of the disclosure may be practiced. These embodiments are described in sufficient detail to enable those of ordinary skill in the art to practice the embodiments of this disclosure, and it is to be understood that other embodiments may be utilized and that process, electrical, and/or structural changes may be made without departing from the scope of the present disclosure. As used herein, “a number of” a particular thing can refer to one or more of such things (e.g., a number of memory devices can refer to one or more memory devices).

As will be appreciated, elements shown in the various embodiments herein can be added, exchanged, and/or eliminated so as to provide a number of additional embodiments of the present disclosure. In addition, as will be appreciated, the proportion and the relative scale of the elements provided in the figures are intended to illustrate certain embodiments of the present invention, and should not be taken in a limiting sense.

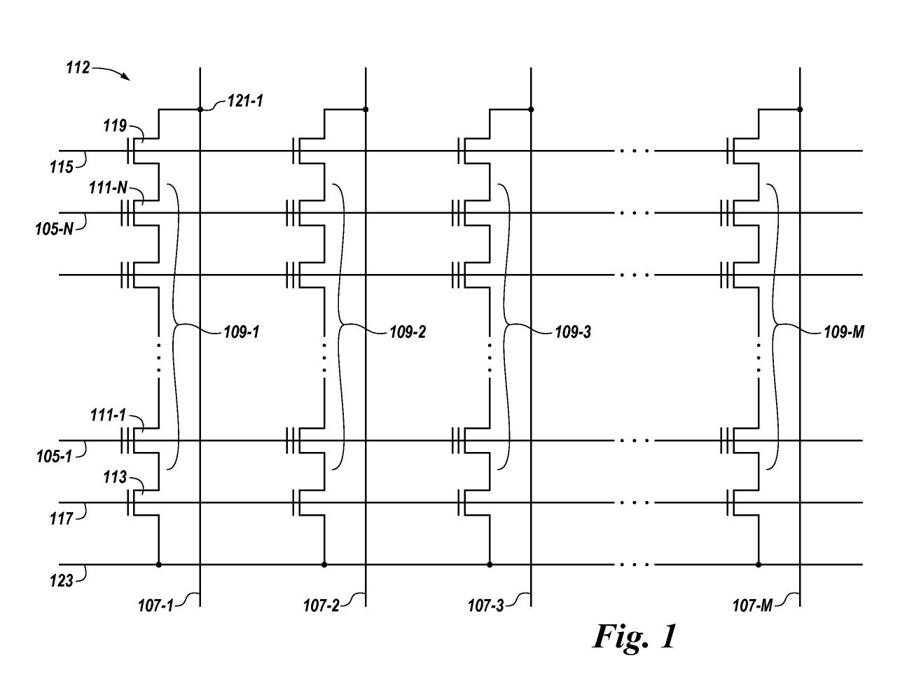

FIG. 1 illustrates a schematic diagram of a portion of a memory array operable in accordance with a number of embodiments of the present disclosure. The embodiment of FIG. 1 illustrates a NAND architecture non-volatile memory array. However, embodiments described herein are not limited to this example. As shown in FIG. 1, memory array 112 includes access lines (e.g., word lines 105-1, . . . , 105-N) and intersecting data lines (e.g., bit lines) 107-1, 107-2, 107-3, . . . , 107-M.

Memory array 112 includes NAND strings 109-1, 109-2, 109-3, . . . , 109-M. Each NAND string includes non-volatile memory cells 111-1, . . . , 111-N, each communicatively coupled to a respective word line 105-1, . . . , 105-N. Each NAND string (and its constituent memory cells) is also associated with a bit line 107-1, 107-2, 107-3, . . . , 107-M. The non-volatile memory cells 111-1, . . . , 111-N of each NAND string 109-1, 109-2, 109-3, . . . , 109-M are connected in series source to drain between a source select gate (SGS) (e.g., a field-effect transistor (FET)) 113, and a drain select gate (SGD) (e.g., FET) 119. Each source select gate 113 is configured to selectively couple a respective NAND string to a common source 123 responsive to a signal on source select line 117, while each drain select gate 119 is configured to selectively couple a respective NAND string to a respective bit line responsive to a signal on drain select line 115.

As shown in the embodiment illustrated in FIG. 1, a source of source select gate 113 is connected to a common source line 123. The drain of source select gate 113 is connected to the source of the memory cell 111-1 of the corresponding NAND string 109-1. The drain of drain select gate 119 is connected to bit line 107-1 of the corresponding NAND string 109-1 at drain contact 121-1. The source of drain select gate 119 is connected to the drain of the last memory cell 111-N of the corresponding NAND string 109-1.

The non-volatile memory cells 111-1, . . . , 111-N can include a charge storage structure such as a floating gate, and a control gate. Memory cells 111-1, . . . , 111-N have their control gates coupled to respective word lines, 105-1, . . . , 105-N. A NOR array architecture would be similarly laid out, except that the string of memory cells would be coupled in parallel between the select gates.

As will be further described herein, subsets of cells coupled to a selected word line (e.g., 105-1, . . . , 105-N) can be programmed (e.g., written) and/or sensed (e.g., read) together (e.g., in parallel). As an example, a program operation can include applying a number of program pulses (e.g., 16V-20V) to a selected word line in order to increase the threshold voltage (Vt) of selected cells coupled to that selected access line to a desired program voltage level corresponding to a target (e.g., desired) data state.

A sense operation, such as a read or program verify operation, can include sensing a voltage and/or current change of a bit line coupled to a selected cell in order to determine the data state of the selected cell. The sense operation can include providing a voltage to (e.g., biasing) a bit line (e.g., bit line 107-1) associated with a selected memory cell above a voltage (e.g., bias voltage) provided to a source line (e.g., source line 123) associated with the selected memory cell. A sense operation could alternatively include precharging the bit line followed with discharge when a selected cell begins to conduct, and sensing the discharge.

Sensing the state of a selected cell can include providing a number of ramped sensing signals (e.g., read voltages) to a selected word line while providing a number of pass signals (e.g., read pass voltages) to the word lines coupled to the unselected cells of the string sufficient to place the unselected cells in a conducting state independent of the Vt of the unselected cells. The bit line corresponding to the selected cell being read and/or verified can be sensed to determine whether or not the selected cell conducts in response to the particular sensing voltage applied to the selected word line. For example, the data state of a selected cell can be determined by the word line voltage at which the bit line current reaches a particular reference current associated with a particular state. Alternatively, the data state of the selected cell can be determined based on whether the bit line current changes by a particular amount or reaches a particular level in a given time period.

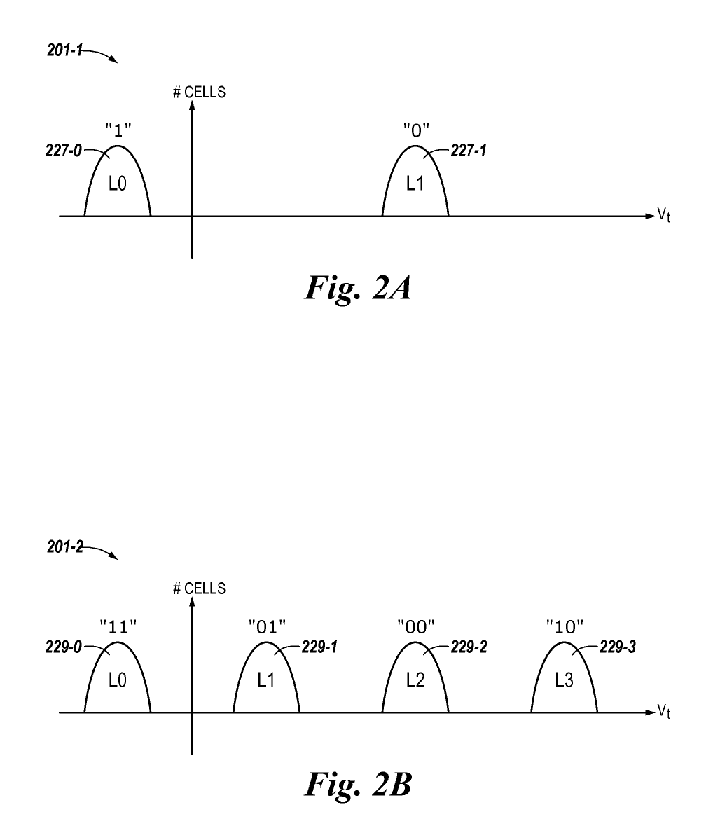

As described further below in connection with FIGS. 2A and 2B, the memory cells 111-1 to 111-N can be operable to store SLC and MLC data (e.g., depending on the number of bits of data stored in each cell). Additionally, the array 112 can be organized as a number of physical blocks of memory cells that can be erased together (e.g., in parallel in a substantially simultaneous manner).

As one of ordinary skill in the art will appreciate, each row of cells (e.g., the cells commonly coupled to a particular word line) can include a number of pages of memory cells (e.g., physical pages). A physical page refers to a unit of programming and/or sensing (e.g., a number of memory cells that are programmed and/or sensed together as a functional group). As one example, each row can comprise multiple physical pages of memory cells (e.g., one or more even pages of memory cells coupled to even-numbered bit lines, and one or more odd pages of memory cells coupled to odd numbered bit lines). Additionally, for embodiments including multilevel cells, a physical page of memory cells can store multiple pages (e.g., logical pages) of data (e.g., an upper page of data and a lower page of data, with each cell in a physical page storing one or more bits towards an upper page of data and one or more bits towards a lower page of data).

FIG. 2A is a diagram 201-1 of a number of threshold voltage distributions corresponding to SLC data, and FIG. 2B is a diagram 201-2 of a number of threshold voltage distributions corresponding to MLC data. As noted above, in a number of embodiments, memory cells (e.g., 111-1 to 111-N) can be programmed as SLCs or MLCs. For instance, a particular cell may store SLC data at particular time and may store MLC data at a different (e.g., later) time.

FIG. 2A includes two threshold voltage (Vt) distributions 227-0 and 227-1 corresponding to SLCs. Vt distribution 227-0 corresponds to a first data state (e.g., L0) and Vt distribution 227-1 corresponds to a second data state (e.g., L1) to which the cells are programmable. In this example, cells programmed to data state L0 represent a stored logic value of “1,” and cells programmed to data state L1 represent a stored logic value of “0;” however, embodiments are not limited to this example.

FIG. 2B includes four Vt distributions 229-0, 229-1, 229-2, and 229-3 corresponding to MLCs. Vt distribution 229-0 corresponds to a first data state (e.g., L0), Vt distribution 229-1 corresponds to a second data state (e.g., L1), Vt distribution 229-2 corresponds to a third data state (e.g., L2), and Vt distribution 229-3 corresponds to a fourth data state (e.g., L3) to which the cells are programmable. In the example shown in FIG. 2B, the MLCs are 2-bit cells (e.g., each cell stores 2 bits of data). In this example, cells programmed to data state L0 represent a stored logic value of “11,” cells programmed to data state L1 represent a stored logic value of “01,” cells programmed to data state L2 represent a stored logic value of “00,” and cells programmed to data state L3 represent a stored logic value of “10;” however, embodiments are not limited to these data assignments. Also, embodiments are not limited to 2-bit MLCs.

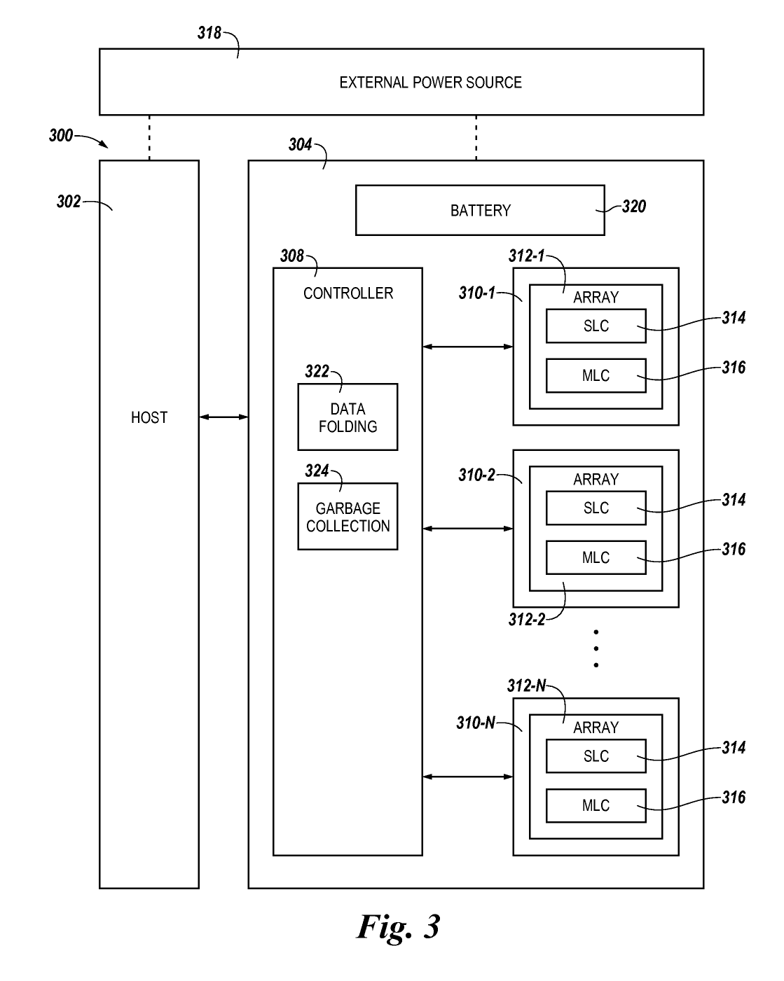

FIG. 3 is a block diagram of an apparatus in the form of a computing system 300 including at least one memory system 304 in accordance with a number of embodiments of the present disclosure. As used herein, a memory system 304, a controller 308, or a memory device 310 might also be separately considered an “apparatus.” In this example, system 300 includes a host 302 coupled to memory system 304. The system 300 can include separate integrated circuits or both the host 302 and the memory system 304 can be on the same integrated circuit. The system 300 can be a portable device such as a mobile telephone, personal laptop, digital camera, etc. In a number of embodiments, the system 300 can be selectively coupled to (e.g., plugged into) an external power source 318, which can be an AC power source, for example. The memory system 304 can be a solid state drive (SSD), for instance, and can include a controller 308 and a number of memory devices 310-1 to 310-N, which provide a storage volume for the memory system 304.

The memory devices 310-1 to 310-N (referred to generally as memory devices 310) each comprise a respective array of memory cells 312-1 to 312-N (referred to generally as arrays 312). The arrays 312 can be arrays such as array 112 shown in FIG. 1. For example, the memory cells of arrays 312 can be NAND flash memory cells operable to store SLC data and MLC data. In FIG. 3, portion 314 of arrays 312 represent cells storing SLC data (e.g., SLCs) and portion 316 of arrays 312 represent cells storing MLC data (e.g., MLCs). Embodiments are not limited to NAND flash arrays and may include other types of arrays such as DRAM arrays, SRAM arrays, STT RAM arrays, PCRAM arrays, RRAM arrays, and/or NOR flash arrays, for instance.

The controller 308 can be coupled to the memory devices 310 via a number of channels and can be used to transfer data between the memory system 304 and a host 302. Although not shown in FIG. 3, the host 302 can be coupled to the system 304 via an interface. The interface can be in the form of a standardized interface. For example, the interface can be a serial advanced technology attachment (SATA), peripheral component interconnect express (PCIe), or a universal serial bus (USB), among other interfaces. In general, the interface can provide an interface for passing control, address, data, and other signals between the memory system 304 and a host 302 having compatible receptors for the interface.

Host 302 can be a host system such as a personal laptop computer, a desktop computer, a digital camera, a mobile telephone, or a memory card reader, among various other types of hosts and/or mobile devices. Host 302 can include a system motherboard and/or backplane and can include a number of memory access devices (e.g., a number of processors). Host 302 can also be a memory controller, such as where memory devices 310 include an on-die controller. For example, the controller 308 may or may not be located on a same die as one or more of the memory devices 310.

The controller 308 can be implemented in software, hardware, firmware, and/or combinations thereof. For example, the controller 308 can be a state machine, a sequencer, or some other type of controller and can communicate with the memory devices 310 to control data read, write, and erase operations, among other operations. The controller 308 can be responsible for executing instructions from the host 302 and/or from the memory devices 310. In a number of embodiments, and as shown in FIG. 3, the controller 308 can include a data folding component 322 and a garbage collection component 324, which can be implemented in software, firmware, hardware, and/or a combination thereof. The components 322 and 324 can be configured to perform data folding operations and/or garbage collection operations such as described further herein. In a number of embodiments, the components 322 and 324, or portions thereof, may be located on and/or executed by the host 302.

A data folding operation can include folding SLC data into MLC data. For instance, folding can include rewriting data stored in SLC portion 314 in MLC portion 316. It is noted that an array (e.g., 312) may or may not include both an SLC portion and an MLC portion at a particular time. For example, the memory cells of the arrays 312 may store SLC or MLC data, so it is possible for all of the cells of an array to store only SLC data or only MLC data at a particular time.

In a number of embodiments, the system 300 can operate in multiple power modes. For example, the system 300 can operate in a first power mode (e.g., a DC power mode) and a second power mode (e.g., an AC power mode). For instance, as shown in FIG. 3, system 300 includes a battery 320 providing a DC power source for operating in DC power mode, and system 300 can be coupled to an external power source 318 (e.g., an AC power source) for operating in AC power mode (e.g., when the system 300 is plugged in to electrical outlet). Although not shown in FIG. 3, the system 300 may include a charging component configured to charge/recharge the battery 320 (e.g., when coupled to the external power source 318). Although the battery 320 is shown as part of memory system 304, the battery 320 can serve as a DC power source for the host 302 and may be located on the host 302. Additionally, embodiments are not limited to a particular type of DC and/or AC power source.

In a number of embodiments, the performance of operations such as data folding and/or garbage collection can be based on a variety of factors. For example, in a number of embodiments, the determination of whether data folding and/or garbage collection occurs is based on the power mode of an apparatus. For instance, data folding and/or garbage collection may be reserved for instances in which the apparatus is operating in a first power mode, such as an AC power mode (e.g., when the apparatus is plugged in), such that data folding and/or garbage collection is delayed while the apparatus is in a second power mode, such as a DC power mode (e.g., operating on battery power). In a number of embodiments, a memory system (e.g., 304) can determine the particular power mode in which it is operating and/or the amount of battery life remaining in various manners. For example, a dedicated pin may be used to indicate (e.g., to controller 308) if the system is operating in AC or DC power mode. As another example, controller 308 can be configured to issue a particular command to host 302 (e.g., to the host operating system), which could respond with an indication of the current power mode and/or remaining battery life. Alternatively, or additionally, a protocol could be used in which the host writes information indicating the power mode and/or battery life to registers, which could then be read by the controller at will, or at particular intervals, for instance. The host could also provide indications to the controller in response to power mode changes and/or in response to the remaining battery life reaching particular threshold levels. Embodiments are not limited to a particular manner in which a system (e.g., 300) is made aware of the current power mode and/or remaining battery life.

The timing of when operations such as data folding and/or garbage collection are performed can also be based on factors such as the capacity of a DC power source (e.g., remaining battery life), the available storage capacity of the system, the amount and/or status of cold data, the amount of unanswered I/O requests, and/or the amount of garbage collection opportunities available, among various other factors.

As an example, certain particular operations, such as a number of data folding and/or garbage collection operations may be performed based on whether a threshold amount of battery life remains. For instance, certain garbage collection operations may be delayed (e.g., until the apparatus is operating in AC mode) unless the remaining battery life is at or above a threshold value (e.g., 50%, 75%, etc.). Other factors that can be used to determine whether or not to perform data folding operations can include the amount of available storage capacity of the memory and/or over-provisioning available. For example, even if the apparatus is operating in a DC power mode (e.g., via battery power), data folding may be allowed to proceed in order to avoid exceeding the available capacity of the memory (e.g., due to an amount of write operations requested from the host which would result in exceeding the available memory capacity).

In a number of embodiments, priority with respect to folding may be given to “cold” SLC data. “Cold” data can refer to data that is not often changed and/or not often accessed as compared to other data. The coldness of data may be identified by a memory system (e.g., 304) tracking I/O requests to the data and/or by a host (e.g., 302), which may track the frequency with which memory space is written, for example. As such, SLC data that is relatively “colder” than other SLC data may be selected for folding into MLC data first. In addition, the folding of SLC data into MLC data may be based on the amount of “cold” SLC data. For instance, the folding of SLC data into MLC data may be delayed until a threshold capacity of cold SLC data is reached.

Another factor that can be used to determine whether to and/or when to perform data folding operations can be the amount of and/or frequency of unanswered service requests for I/O from a host (e.g., 302), for instance. For example, even if a system (e.g., 300) is not operating in a DC power mode (e.g., the system is coupled to an AC power source rather than operating on battery power), the QoS (quality of service) can be affected by the performance of data folding operations. Therefore, it may be beneficial to prevent data folding from occurring in instances in which the quantity of I/O requests are relatively high in order to enhance the QoS experience for a user. As an example, the determination of whether to perform data folding may depend on whether a quantity of unanswered service requests is above a threshold quantity (e.g., regardless of whether the system is operating in an AC or DC power mode). An unanswered service request can refer to a request (e.g., from a host such as host 302) that is not performed within a particular time duration allowed for the request to be performed.

Another factor that can be used to determine whether to and/or when to perform data folding operations can be the amount of garbage collection opportunities identified. For example, the write amplification factor of a memory system (e.g., 304) can be reduced by delaying and/or preventing SLC data to MLC data folding until a threshold number of garbage collection opportunities exist. Delaying garbage collection can improve the efficiency associated with the particular garbage collection algorithm, for instance. Therefore, in a number of embodiments, the system may delay performing folding operations even if the system is operating in AC power mode unless and/or until the garbage collection opportunities reach a particular threshold, which can result in reducing the write amplification factor over the life of the system. As an example, the write amplification factor can refer to the ratio of the amount of data written to memory (e.g., memory devices 310, which can be flash memory such as an SSD) to the amount of data written by the host (e.g., host 302).

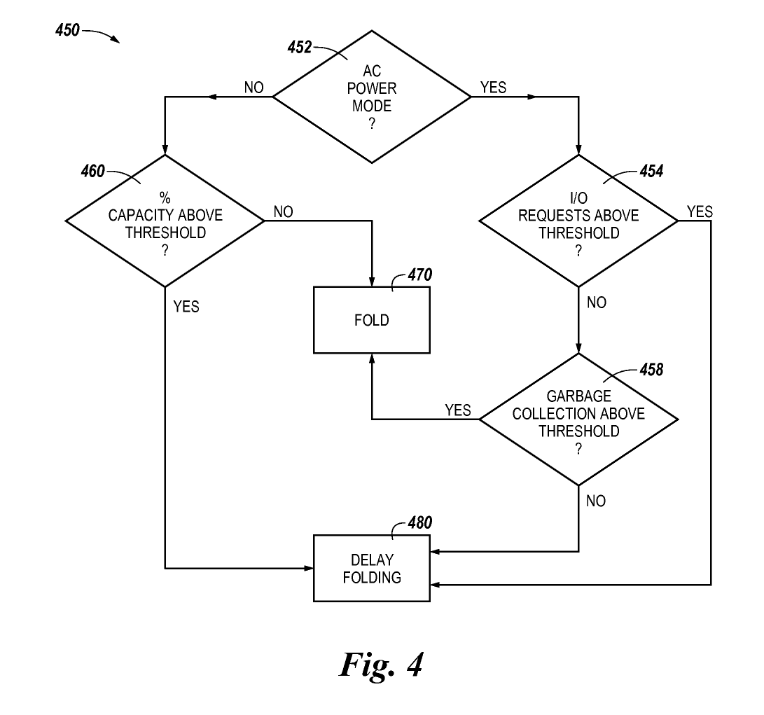

As described further below in connection with FIG. 4, a number of embodiments of the present disclosure can include implementing a policy to determine whether to and/or when to perform data folding operations. The policy can include a number of factors such as those described above.

FIG. 4 is a flow chart 450 illustrating a method of operating an apparatus in accordance with a number of embodiments of the present disclosure. Flow chart 450 implements an example policy associated with determining whether or not to perform data folding (e.g., folding SLC data into MLC data) based on a number of factors.

At 452, a determination is made as to whether the apparatus (e.g., apparatus 300 shown in FIG. 3) is operating in an AC power mode (e.g., coupled to an external power source such as 318).

As shown at 454, if the apparatus is in AC power mode, it is determined whether the I/O requests (e.g., from a host such as host 302) are above a threshold. As discussed above, this may include determining whether there are a threshold number of unanswered I/O requests and/or whether there are continuous I/O requests such that performing folding operations may reduce the QoS experienced by a user. If at 454 it is determined that the number of I/O requests are above the threshold, then data folding is delayed (e.g., as shown at 480). If the number of I/O requests are not above the threshold, then, as shown at 458, a determination is made regarding whether garbage collection is above a threshold (e.g., whether a threshold number of garbage collection opportunities are available). If it is determined at 458 that the garbage collection opportunities are above the threshold level, then data folding proceeds (e.g., as shown at 470), and if it is determined that the garbage collection opportunities are not above the threshold, then data folding is delayed (e.g., as shown at 480).

As shown at 460, a determination is made regarding whether the percentage available capacity of the memory is above a threshold level. If the available capacity is not above the threshold, then data folding proceeds (despite the fact that the system is not in AC power mode); however, if the available capacity is above the threshold, then data folding is prevented and/or delayed. That is, data folding may be warranted despite an apparatus operating on battery power, for example, if a present number of write requests will exceed the available capacity of the memory.

In some instances, a system may transition from AC power mode to DC power mode while a data folding operation is in progress. In a number of embodiments, a data folding operation that begins while the system is in AC power mode may be allowed to finish despite a transition to DC power mode.

Although specific embodiments have been illustrated and described herein, those of ordinary skill in the art will appreciate that an arrangement calculated to achieve the same results can be substituted for the specific embodiments shown. This disclosure is intended to cover adaptations or variations of a number of embodiments of the present disclosure. It is to be understood that the above description has been made in an illustrative fashion, and not a restrictive one. Combination of the above embodiments, and other embodiments not specifically described herein will be apparent to those of skill in the art upon reviewing the above description. The scope of the number of embodiments of the present disclosure includes other applications in which the above structures and methods are used. Therefore, the scope of a number of embodiments of the present disclosure should be determined with reference to the appended claims, along with the full range of equivalents to which such claims are entitled.

In the foregoing Detailed Description, some features are grouped together in a single embodiment for the purpose of streamlining the disclosure. This method of disclosure is not to be interpreted as reflecting an intention that the disclosed embodiments of the present disclosure have to use more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. An apparatus, comprising:
a memory comprising an array of memory cells operable to store single-level cell (SLC) data and multi-level cell (MLC) data; and
a controller coupled to the memory and configured to:
responsive to the apparatus being in a first power mode, fold SLC data into MLC data; and
prevent SLC data from being folded into MLC data responsive to the apparatus being in a second power mode.

2. The apparatus of claim 1, wherein the first power mode is an alternating current (AC) power mode, and wherein the second power mode is a direct current (DC) power mode.

3. The apparatus of claim 2, wherein the apparatus operates in the first power mode when coupled to an AC power source, and wherein the apparatus operates in the second power mode when decoupled from the AC power source.

4. The apparatus of claim 3, wherein the AC power source is an external AC power source, and wherein apparatus further comprises an internal DC power source rechargeable via the external AC power source.

5. The apparatus of claim 1, wherein the controller is further configured to:
determine whether the apparatus is in the first power mode or the second power mode;
determine an availability of a garbage collection routine;
execute the garbage collection routine responsive to a determination that the apparatus is in the first power mode; and
delay execution of the garbage collection routine until the apparatus is in the first power mode responsive to a determination that the apparatus is in the second power mode.

6. The apparatus of claim 1, wherein the apparatus is a mobile device and the array is a flash memory array.

7. A method, comprising:
storing data in an apparatus comprising a memory operable to store single-level cell (SLC) data and multi-level cell (MLC) data; and
determining whether to fold SLC data into MLC data at least based on a power mode in which the apparatus is operating.

8. The method of claim 7, further comprising:
responsive to the apparatus being in an AC power mode, folding SLC data into MLC data; and
responsive to the apparatus being in a DC power mode, preventing SLC data from being folded into MLC data.

9. The method of claim 7, further comprising:
determining a particular power mode in which the apparatus is operating;
responsive to a determination that the particular power mode is an AC power mode, determining whether to fold SLC data into MLC data based on a number of particular factors.

10. The method of claim 9, wherein determining whether to fold SLC data into MLC data based on the number of particular factors includes determining whether a quantity of input/output (I/O) requests from a host is above a threshold quantity prior to folding the SLC data into MLC data.

11. The method of claim 9, wherein determining whether to fold SLC data into MLC data based on the number of particular factors includes determining whether a quantity of garbage collection opportunities is above a threshold quantity prior to folding the SLC data into MLC data.

12. The method of claim 7, further comprising:
determining a particular power mode in which the apparatus is operating;
responsive to a determination that the particular power mode is a DC power mode, determining whether to fold SLC data into MLC data based on a number of particular factors.

13. The method of claim 12, wherein determining whether to fold SLC data into MLC data based on the number of particular factors includes determining whether a remaining battery life is above a threshold level, and wherein the method includes:
folding the SLC data into MLC data responsive to a determination that the remaining battery life is above the threshold level; and
delaying the folding of the SLC data into MLC data responsive to a determination that the remaining battery life is not above the threshold level.

14. The method of claim 12, wherein determining whether to fold SLC data into MLC data based on the number of particular factors includes determining whether an available capacity of the memory is above a threshold level, and wherein the method includes:
folding the SLC data into MLC data responsive to a determination that the available capacity is not above the threshold level; and
delaying the folding of the SLC data into MLC data responsive to a determination that the available capacity is above the threshold level.

15. An apparatus, comprising:
a memory comprising an array of memory cells operable to store single-level cell (SLC) data and multi-level cell (MLC) data; and
a controller coupled to the memory and configured to:
determine a power mode in which the apparatus is operating; and
determine whether to fold SLC data into MLC data at least based on the determined power mode.

16. The apparatus of claim 15, wherein the apparatus comprises a battery, and wherein, responsive to a determination that the apparatus is operating in a DC power mode, the controller is further configured to prevent folding of SLC data into MLC data unless a battery life of the battery is above a threshold level.

17. The apparatus of claim 15, wherein, responsive to a determination that the apparatus is operating in a DC power mode, the controller is further configured to prevent folding of SLC data into MLC data unless an available capacity of the memory is not above a threshold level.

18. The apparatus of claim 15, wherein responsive to a determination that the apparatus is operating in an AC power mode, the controller is further configured to prevent folding of SLC data into MLC data responsive to a determination that a quantity of input/output (I/O) requests from a host is above a threshold quantity.

19. The apparatus of claim 15, wherein responsive to a determination that the apparatus is operating in an AC power mode, the controller is further configured to prevent folding of SLC data into MLC data responsive to a determination that a quantity of garbage collection opportunities is not above a threshold quantity.

20. The apparatus of claim 15, wherein the controller comprises a data folding component and a garbage collection component.

21. The apparatus of claim 15, wherein the apparatus comprises a battery that is rechargeable via an external AC power source.

22. The apparatus of claim 15, wherein the array of memory cells is a NAND array of flash memory cells.
